(19) United States
(12) Patent Application Publication
(10) Pub. No.: US 2023/0126853 A1
(43) Pub. Date: Apr. 27, 2023

(54) SENSOR AND ELECTRONIC DEVICE

(71) Applicants: SHARP KABUSHIKI KAISHA, Sakai City, Osaka (JP); NATIONAL UNIVERSITY CORPORATION NARA INSTITUTE OF SCIENCE AND TECHNOLOGY, Ikoma-shi, Nara (JP); KYUSHU UNIVERSITY, NATIONAL UNIVERSITY CORPORATION, Fukuoka-shi, Fukuoka (JP)

(72) Inventors: ATSUSHI FUKUI, Sakai City, Osaka (JP); SATOSHI SHIMIZU, Sakai City, Osaka (JP); Yuki KYODA, Sakai City, Osaka (JP); TOMOHISA YOSHIE, Sakai City, Osaka (JP); Yuito SUGATA, Ikoma-shi, Nara (JP); Yutaka ARAKAWA, Fukuoka-shi, Fukuoka (JP); DAISUKE TOYOSHIMA, Sakai City, Osaka (JP)

(21) Appl. No.: 17/799,209

(22) PCT Filed: Feb. 17, 2021
(86) PCT No.: PCT/JP2021/005967

§ 371 Date: Jan. 3, 2023

(30) Foreign Application Priority Data
Feb. 19, 2020 (JP) 2020-026631

(51) Int. Cl. G01R 19/00; G01P 15/00; H02S 50/10

(52) U.S. Cl. CPC G01R 19/0084; G01P 15/00; H02S 50/10; G04C 10/02

(57) ABSTRACT

In a sensor used in an energy harvesting system, electric power generated by a solar cell module is more efficiently utilized. In a sensor (100), a resistor (3) is connected in parallel with one of a first solar cell module (1a) and a second solar cell module (1b) that have mutually different current-voltage characteristics in the same illuminance environment and in series with the other one of the first solar cell module (1a) and the second solar cell module (1b). A first voltmeter (4a) measures a voltage (V1) across the first solar cell module (1a), and a second voltmeter (4b) measures a voltage (V2) across the second solar cell module (1b). A load (6) is fed with the electric power generated by the first solar cell module (1a) and the second solar cell module (1b).

### TECHNICAL FIELD

The present disclosure, in an aspect thereof, relates to sensors for use in energy harvesting systems.

### BACKGROUND ART

Patent Literature 1 discloses technology that reduces the size of mobile electronic devices including solar cells. Patent Literature 1 discloses a watch-type device (i.e., a smart watch as a wearable device) as an example of such mobile electronic devices. This mobile electronic device is capable of geolocation (GPS geolocation) based on GPS (global positioning system) functions.

It should be noted however that in the conventional electronic device (e.g., the mobile electronic device described in Patent Literature 1), if a signal from a GPS satellite (GPS signal) cannot be properly received, it is impossible to perform GPS geolocation. For instance, when the user wearing the smart watch is inside a building, the GPS signal may possibly be blocked by the outer wall of the building. In such cases, the electronic device is incapable of GPS geolocation.

To address these problems in GPS geolocation, Non-patent Literature 1 proposes a sensor for use in an energy harvesting system. This sensor of Non-patent Literature 1 is referred to as an EHAAS (energy harvester as a sensor). In the sensor of Non-patent Literature 1, the electric power (more particularly, the voltage) generated by each power generation element (e.g., solar cell module) is measured. Calculations are then done for geolocation on the basis of the environment dependency of each voltage.

### CITATION LIST

### Patent Literature

Patent Literature 1: Japanese Unexamined Patent Application Publication, Tokukai, No. 2019-32221

### Non-patent Literature

Non-patent Literature 1; “EHAAS: Energy Harvesters As A Sensor for Place Recognition on Wearables,” Yoshinori Umetsu et al. IEEE International Conference on Pervasive Computing and Communications (PerCom 2019)

### SUMMARY OF INVENTION

### Technical Problem

However, as will be described later, there is still room for improvement in a peripheral circuit configuration for the solar cell module in the sensor for use in the energy harvesting system. The present disclosure, in an aspect thereof, has an object to more efficiently utilize the electric power generated by the solar cell module in the sensor.

### Solution to Problem

To address these problems, the present disclosure, in one aspect thereof, is directed to a sensor for use in an energy harvesting system, the sensor including: a first solar cell module; a second solar cell module connected to the first solar cell module; and a resistor connected in parallel with one of the first solar cell module and the second solar cell module and in series with another one of the first solar cell module and the second solar cell module, wherein the first solar cell module and the second solar cell module have mutually different current-voltage characteristics in a same illuminance environment, and the sensor further including: a first voltmeter configured to measure a first voltage that is a voltage across the first solar cell module; a second voltmeter configured to measure a second voltage that is a voltage across the second solar cell module; and a load to which an electric power generated by the first solar cell module and the second solar cell module is supplied.

### Advantageous Effects of Invention

According to a sensor in accordance with an aspect of the present disclosure, it becomes possible to more efficiently utilize the electric power generated by a solar cell module.

### BRIEF DESCRIPTION OF DRAWINGS

FIG. 1 is a schematic perspective view of a sensor in accordance with Embodiment 1.

FIG. 2 is a diagram representing a circuit configuration of the sensor in FIG. 1.

FIG. 3 is a set of graphs representing exemplary I-V curves for a first solar cell module and a second solar cell module respectively.

FIG. 4 is a table showing exemplary current-voltage characteristics for the first solar cell module and the second solar cell module under various illuminances.

FIG. 5 is a set of diagrams representing a circuit configuration of a sensor in accordance with Comparative Example 1.

FIG. 6 is a diagram representing a circuit configuration of a sensor in accordance with Comparative Example 2.

FIG. 7 is a diagram representing a circuit configuration of a sensor in accordance with Comparative Example 3.

FIG. 8 is a diagram representing a circuit configuration of a sensor in accordance with Embodiment 2.

FIG. 9 is a diagram representing a circuit configuration of a sensor in accordance with Embodiment 3.

FIG. 10 is an illustration of a smart watch in accordance with Embodiment 4.

### DESCRIPTION OF EMBODIMENTS

### Embodiment 1

The following will describe a sensor 100 in accordance with Embodiment 1. For convenience of description, members of Embodiment 2 and any subsequent embodiments that have the same function as members described in Embodiment 1 will be indicated by the same reference numerals, and description thereof is not repeated. Description of the same matters as in publicly known technology is also omitted where appropriate. The device structures and circuit configurations shown in the drawings are mere examples for convenience of description. Therefore, the relative positions of the members are not necessarily limited to the examples shown in the drawings. Additionally, numerical values given in the specification are also mere examples. Throughout the present specification, the language, “A to B,” where A and B are both numerical values refers to “greater than or equal to A and less than or equal to B” unless otherwise mentioned. In addition, the term, “connected,” means “electrically connected” throughout the present specification unless otherwise mentioned.

### Configuration of Sensor 100

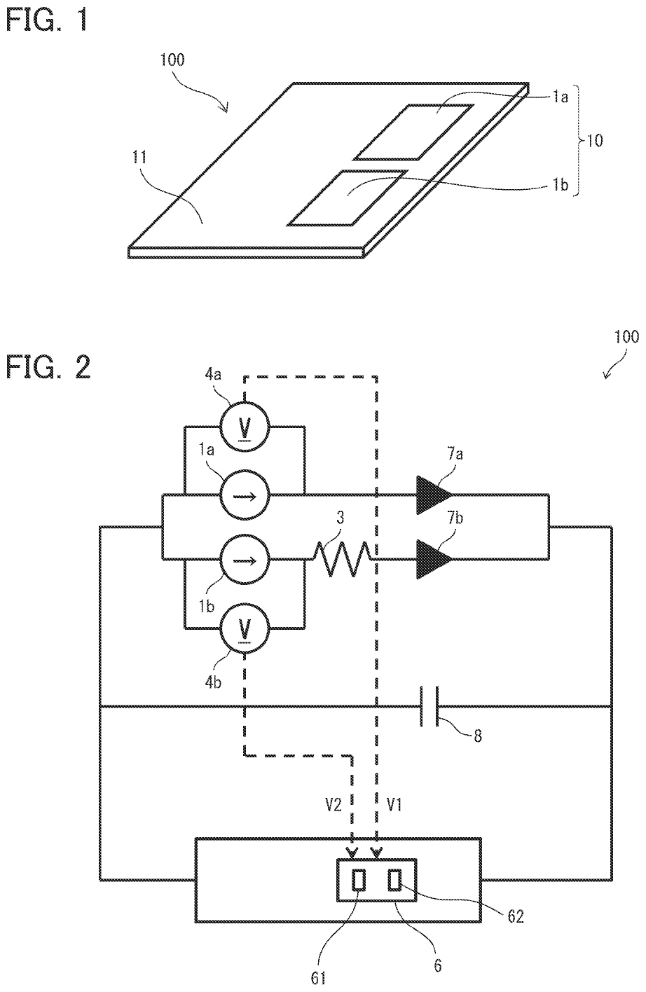

FIG. 1 is a schematic perspective view of the sensor 100. The sensor 100 is an example of a sensor for use in an energy harvesting system (EHAAS). As will be described in Embodiment 4 below, the sensor 100 may be built in, for example, a smart watch. The sensor 100 includes a group of solar cell modules 10 and a housing 11.

The group of solar cell modules in accordance with an aspect of the present disclosure includes a plurality of (two or more) solar cell modules. The solar cell modules in the group of solar cell modules are connected to each other (see also Embodiment 3, which will be described later). In Embodiment 1, two solar cell modules (a first solar cell module 1a and a second solar cell module 1b) constitute the group of solar cell modules 10. The solar cell module in accordance with an aspect of the present disclosure is an example of a power generation element. This power generation element may be more specifically referred to as an energy harvesting power generation element.

The housing 11 is a member for housing the first solar cell module 1a and the second solar cell module 1b. The first solar cell module 1a and the second solar cell module 1b are respectively positioned on the surface of the housing 11 in such a manner that light-receiving faces thereof are exposed. The housing 11 in FIG. 1 is an example of a card-type housing. However, the shape of the housing 11 is not necessarily limited to the example of FIG. 1.

FIG. 2 is a diagram representing a circuit configuration of the sensor 100. Referring to FIG. 2, the sensor 100 includes, in addition to the first solar cell module 1a and the second solar cell module 1b, a resistor 3 (first resistor), a first voltmeter 4a, a second voltmeter 4b, a load 6, a first diode 7a, a second diode 7b, and a power storage element 8. In the example of FIG. 2, the load 6 includes a memory unit 61 and a timer 62. In FIG. 2, the first solar cell module 1a and the second solar cell module 1b are each represented by an electrical circuit symbol for a current source.

In the sensor 100, the first solar cell module 1a and the second solar cell module 1b are connected in parallel. Throughout the following description, the voltages across the first solar cell module 1a and the second solar cell module 1b (output voltages of the first solar cell module 1a and the second solar cell module 1b) will be referred to as V1 and V2 respectively. V1 and V2 may be referred to as a first voltage and a second voltage respectively. In the present specification, V1 and V2 may collectively be referred to as V.

Similarly, the currents (output currents) of the first solar cell module 1a and the second solar cell module 1b will be referred to as I1 and I2 respectively. I1 and I2 may be referred to as a first current and a second current respectively. In the present specification, I1 and I2 may collectively be referred to as I. Additionally, the output electric powers (hereinafter, may be referred to simply as the “powers”) of the first solar cell module 1a and the second solar cell module 1b will be referred to as P1 and P2 respectively. P1 and P2 may be referred to as a first output electric power and a second output electric power respectively. In the present specification, P1 and P2 may collectively be referred to as P. P is given by P=V×I.

The first voltmeter 4a is connected in parallel with the first solar cell module 1a. In the example of Embodiment 1, the first voltmeter 4a measures V1 at every first time interval. The second voltmeter 4b is a voltmeter paired with the first voltmeter 4a. The second voltmeter 4b is connected in parallel with the second solar cell module 1b. The second voltmeter 4b measures V2 at every second time interval. In the example of FIG. 2, the first voltmeter 4a feeds the load 6 (more specifically, the memory unit 61) with a measured value of V1 at every first time interval. Similarly, the second voltmeter 4b feeds the load 6 with a measured value of V2 at every second time interval. The first time interval and the second time interval may be set to any lengths of time (time intervals) respectively and are not limited in any particular manner. As an example, the first time interval and the second time interval may be set to any lengths of time from 0.01 milliseconds to 3 hours respectively. The first time interval may be equal to the second time interval. The first time interval may not be equal to the second time interval.

However, the first voltmeter 4a and the second voltmeter 4b do not necessarily measure V1 and V2 at every fixed time interval respectively. A situation is discussed here as an example where the load 6 includes an acceleration sensor. In such a case, the first voltmeter 4a may measure V1, and the second voltmeter 4b may measure V2, when the acceleration sensor has detected a change in acceleration that is greater than or equal to a prescribed amount. Note that the acceleration sensor is not necessarily provided to the load 6. The sensor 100 needs only to include the acceleration sensor.

The resistor 3 needs only to be connected (i) in parallel with one of the first solar cell module 1a and the second solar cell module 1b and (ii) in series with the other one of the first solar cell module 1a and the second solar cell module 1b. By providing the resistor 3, V1 and V2 are outputted as different values. In the example of FIG. 2, the resistor 3 is connected in parallel with the first solar cell module 1a and in series with the second solar cell module 1b. The resistor 3 has a resistance value of 330Ω to 50 kΩ.

The first diode 7a is connected in series with the first solar cell module 1a. The first diode 7a is provided to prevent reverse biasing of the first solar cell module 1a. The second diode 7b is connected in series with the second solar cell module 1b. The second diode 7b is provided to prevent reverse biasing of the second solar cell module 1b.

The load 6 and the power storage element 8 are connected in parallel with the first solar cell module 1a and the second solar cell module 1b (i.e., the group of solar cell modules 10). Therefore, the load 6 and the power storage element 8 are each fed with electric power from the group of solar cell modules 10. The power storage element 8 stores the electric power fed from the group of solar cell modules 10. In the example of FIG. 2, the power storage element 8 is a capacitor.

The load 6 consumes the electric power fed from the group of solar cell modules 10. The load 6 may be any device driven by this electric power. As an example, the load 6 may be a microcomputer for controlling each section of the sensor 100. Each of the memory unit 61 and the timer 62 may be understood as an example of the load 6. In the example of FIG. 2, the memory unit 61 records (i) the measured value of V1 fed from the first voltmeter 4a and (ii) the measured value of V2 fed from the second voltmeter 4b.

The timer 62 may be realized by a realtime-clock function of a microcomputer. As an example, the timer 62 registers (i) the time at which the measured value of V1 is obtained by the first voltmeter 4a (first time) and (ii) the time at which the measured value of V2 is obtained by the second voltmeter 4b (second time). In this case, the memory unit 61 may additionally record the first time and the second time registered by the timer 62. As described here, the memory unit 61 is capable of recording the respective time-series data of the measured values of V1 and the measured values of V2.

Note that the timer 62 may register a time at which the electric power stored in the power storage element 8 has exceeded a prescribed value. In this case, the memory unit 61 may additionally record this time.

### Example of Current-Voltage Characteristics of Each Solar Cell Module

The solar cell modules in the group of solar cell modules in accordance with an aspect of the present disclosure are structured to exhibit different current-voltage characteristics (I-V characteristics) from each other in the same illuminance environment. The current-voltage characteristics of each solar cell module may be rendered different from those of the other solar cell modules by, for example, (i) each solar cell module being built around a different type of solar cell, (2) each solar cell module including a different number of series-connected solar cells, or (3) each solar cell module having a different light-receiving area (more specifically, effective light-receiving area).

The first solar cell module 1a of Embodiment 1 is a dye-sensitized solar cell module. This dye-sensitized solar cell module includes six series-connected, dye-sensitized solar cells. The first solar cell module 1a has a light-receiving area of 30 cm². Meanwhile, the second solar cell module 1b of Embodiment 1 is an a-Si (amorphous silicon) solar cell module. This a-Si solar cell module includes eight series-connected, a-Si solar cells. The second solar cell module 1b has a light-receiving area of 55 cm².

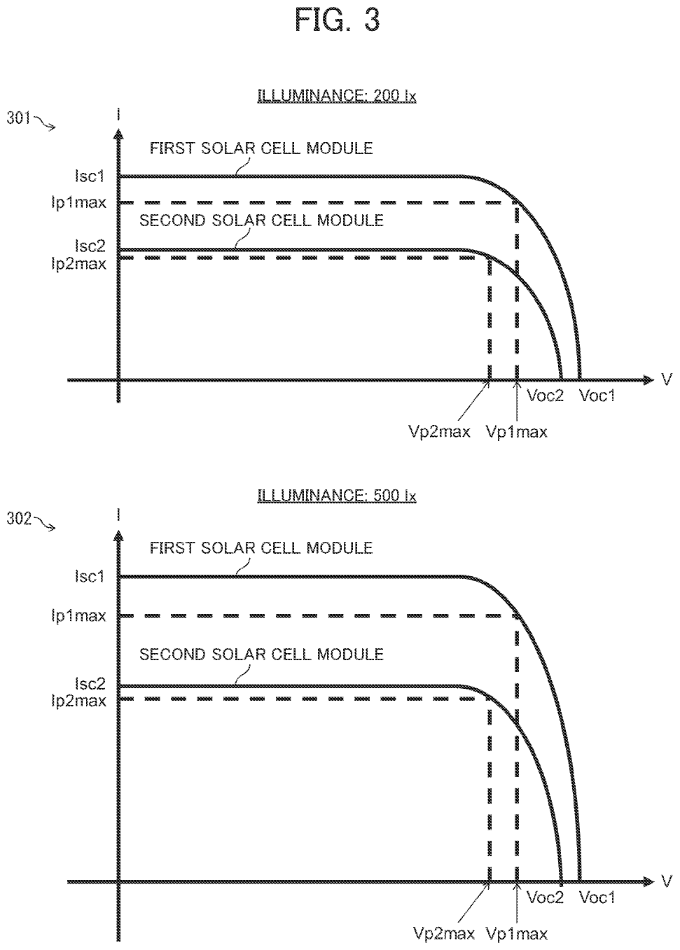

FIG. 3 is a set of graphs representing exemplary current-voltage characteristics curves (hereinafter, may be referred to as “I-V curve”) for the first solar cell module 1a and the second solar cell module 1b respectively. The line denoted by 301 in FIG. 3 is an exemplary I-V curve under an illuminance of 200 1×. The line denoted by 302 in FIG. 3 is an exemplary I-V curve under an illuminance of 500 1×. In these graphs, the horizontal axis represents current (I), and the vertical axis represents voltage (V).

Voc1 and Voc2 denote the open-circuit voltages (Voc) of the first solar cell module 1a and the open-circuit voltage (Voc) of the second solar cell module 1b respectively. Isc1 and Isc2 denote the short-circuit currents (Isc) of the first solar cell module 1a and the short-circuit current (Isc) of the second solar cell module 1b respectively. Throughout the following description, an I-V curve for the first solar cell module 1a may be referred to as a first I-V curve, and an I-V curve for the second solar cell module 1b may be referred to as a second I-V curve.

P1 max denotes a maximum value of the product of V and I on the first I-V curve (i.e., maximum value of P1). P1 max is alternatively referred to as a first maximum output electric power. Vp1 max denotes V1 (value on the horizontal axis) at an optimal operating point (point corresponding to P1 max) on the first I-V curve. Vp1 max is alternatively referred to as a first maximum output operating voltage. In addition, Ip1 max denotes I1 (value on the vertical axis) at that optimal operating point. Ip1 max is alternatively referred to as a first maximum output operating current.

Similarly, P2 max denotes a maximum value of the product of V and I on the second I-V curve (i.e., maximum value of P2). P2 max is alternatively referred to as a second maximum output electric power. Vp2 max denotes V2 at an optimal operating point on the second I-V curve. Vp2 max is referred to as a second maximum output operating voltage. In addition, Ip2 max denotes I2 at that optimal operating point. Ip2 max is alternatively referred to as a second maximum output operating current.

In the present specification, Vp1 max and Vp2 max may be collectively referred to as Vp max (maximum output operating voltage). In addition, Ip1 max and Ip2 max may be collectively referred to as Ip max (maximum output operating current). In addition, P1 max and P2 max may be collectively to referred to as P max (maximum output electric power). As described above, there is a relationship: P max=Vp max×Ip max. Therefore, Vp max and Ip max may be described respectively as V and I that correspond to P max.

Referring to FIG. 3, in both cases of illuminances, 200 1× and 500 1×, the following relationships (i) to (iv) hold.

Voc1>Voc2 (i)

Vp1 max>Vp2 max (ii)

Isc1>Isc2 (iii)

Ip1 max>Ip2 max (iv)

As described here, the first solar cell module 1a and the second solar cell module 1b of Embodiment 1 are structured to exhibit mutually different current-voltage characteristics in the same illuminance environment.

As can be clearly understood from the above-described relationships (i) to (iv), in the example of FIG. 3, the relationship, P1 max>P2 max, holds in both cases of illuminances, 200 1× and 500 1× (see also the area of the rectangle indicated by a dotted line in FIG. 3). In view of ease in designing the sensor 100, the relative relationship of the current-voltage characteristics of each solar cell module is preferably preserved as much as possible even when illuminance is changed.

Preferably, in the sensor 100, the relationship, P1 max>P2 max, holds under any illuminance from 200 1× to 500 1×. More preferably, in the sensor 100, the above-described relationships (i) to (iv) hold under any illuminance from 200 1× to 500 1×.

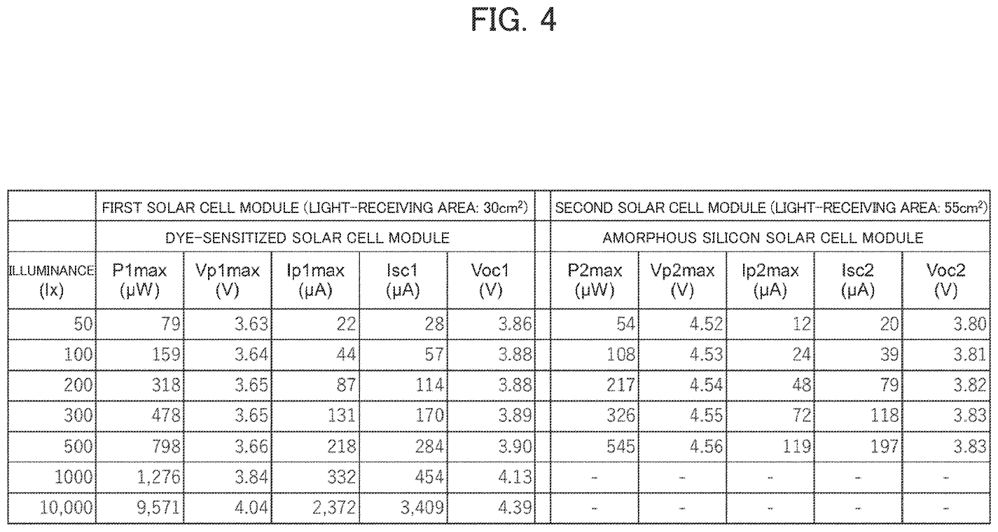

FIG. 4 is a table showing exemplary current-voltage characteristics for the first solar cell module 1a and the second solar cell module 1b under various illuminances. FIG. 4 shows the characteristic values (P1 max, Vp1 max, Ip1 max, Isc1, and Voc1) of the first solar cell module 1a under seven illuminances, 50 1×, 100 1×, 200 1×, 300 1×, 500 1×, 1,000 1×, and 10,000 1×. FIG. 4 also shows the characteristic value (P2 max, Vp2 max, Ip2 max, Isc2, and Voc2) of the second solar cell module 1b under five illuminances, 50 1×, 100 1×, 200 1×, 300 1×, and 500 1×.

Based on the data in FIG. 4, the inventors of the present application (hereinafter, the “inventors”), taking it into account that the sensor 100 (more particularly, the first solar cell module 1a and the second solar cell module 1b) is intended for use in an energy harvesting system, have concluded that following equation (1) preferably holds under the illuminance of 200 1×.

0.1 μA<|Ip1 max−Ip2 max|<500 μA (1)

In the example of FIG. 4, the relationship represented by equation (1) holds under the illuminance of 200 1×.

The inventors have further concluded that following equation (2) preferably holds under the illuminance of 200 1×.

0.01V<|Vp1 max−Vp2 max|<3V (2)

In the example of FIG. 4, the relationship represented by equation (2) holds under the illuminance of 200 1×.

The inventors have further concluded that following equations (3) to (4) preferably hold under the illuminance of 200 1×.

50 μW<P1 max<500 μW (3)

50 μW<P2 max<500 μW (4)

In the example of FIG. 4, the relationships represented by equations (3) to (4) hold under the illuminance of 200 1×.

The inventors have further concluded that following equations (5) to (6) preferably hold under the illuminance of 500 1×.

100 μW<P1 max<5 mW (5)

100 μW<P2 max<5 mW (6)

In the example of FIG. 4, the relationships represented by equations (5) to (6) hold under the illuminance of 500 1×.

The inventors have further concluded that each solar cell module in the group of solar cell modules in accordance with an aspect of the present disclosure preferably has a light-receiving area of from 0.1 cm² to 100 cm². As described above, in Embodiment 1, the first solar cell module 1a has a light-receiving area of 30 cm², and the second solar cell module 1b has a light-receiving area of 55 cm². As described here, the light-receiving areas of the first solar cell module 1a and the second solar cell module 1b of Embodiment 1 both fall in the numerical value range above.

### COMPARATIVE EXAMPLE

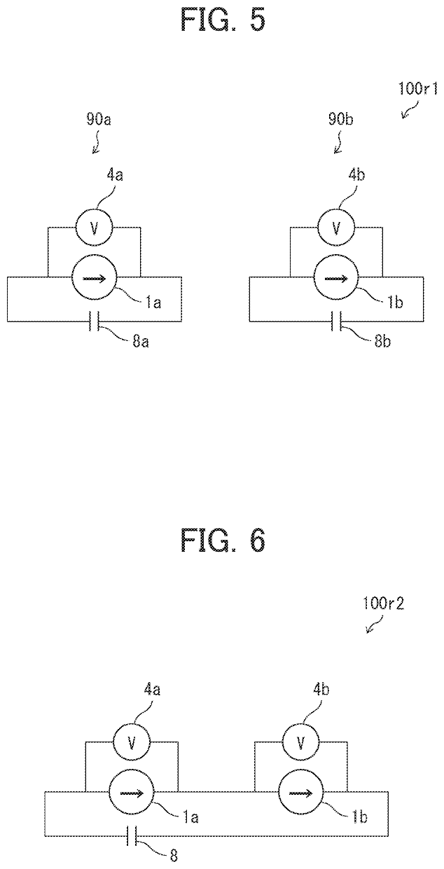

A description is given next of sensors (EHAAS's) of comparative examples before proceeding to describe the effects of the sensor 100. Three comparative examples (Comparative Examples 1 to 3) will be described in the following. Some of the members shown in FIG. 2 (e.g., the load 6) are omitted in the drawings for the comparative examples (FIGS. 5 to 7). Note that the sensors of the comparative examples include no resistor 3, unlike the sensor 100.

### Comparative Example 1

FIG. 5 is a set of diagrams representing a circuit configuration of a sensor 100r1 in accordance with Comparative Example 1. The sensor 100r1 includes a first sub-circuit 90a and a second sub-circuit 90b individually. The first sub-circuit 90a includes a first solar cell module 1a, a first voltmeter 4a, and s first power storage element 8a. Similarly, the second sub-circuit 90b includes a second solar cell module 1b, a second voltmeter 4b, and a second power storage element 8b.

As described here, in Comparative Example 1, the first solar cell module 1a and the second solar cell module 1b are provided as components of the individual sub-circuits. In other words, in Comparative Example 1, unlike Embodiment 1, the first solar cell module 1a and the second solar cell module 1b are not interconnected.

Compact solar cell modules are generally used in an energy harvesting system. Therefore, the first solar cell module 1a has a relatively small output electric power (P1). Therefore, the first sub-circuit 90a is not capable of feeding the load 6 in the first sub-circuit 90a with a sufficient electric power to drive the load 6. In addition, the first power storage element 8a is not capable of storing a sufficient electric power to drive the load 6. This lack of capabilities occurs equally in the second sub-circuit 90b.

Meanwhile, to drive the load 6, the sensor 100l may possibly include an additional solar cell module (or an additional power supply such as a button battery) for powering this load 6. However, to drive the load 6 by an additional solar cell module, the output electric power of the additional solar cell module needs to be set to a somewhat large value. In other words, the light-receiving area of the additional solar cell module needs to be set to a somewhat large value. For these reasons, the provision of an additional solar cell module leads to an increased size of the sensor 100rl.

### Comparative Example 2

FIG. 6 is a diagram representing a circuit configuration of a sensor 100r2 in accordance with Comparative Example 2. Comparative Example 2 is a variation example of Comparative Example 1. In Comparative Example 2, the first sub-circuit 90a and the second sub-circuit 90b of Comparative Example 1 are connected in series. According to Comparative Example 2, unlike Comparative Example 1, both the first solar cell module 1a and the second solar cell module 1b can supply electric power to the common load 6. However, it is again impossible in Comparative Example 2 to supply a sufficient electric power (more particularly, sufficient current) to the load 6.

In Comparative Example 2, unlike Embodiment 1, the first solar cell module 1a and the second solar cell module 1b are connected in series. Therefore, in Comparative Example 2, regardless of whether the first solar cell module 1a and the second solar cell module 1b have the same or different current-voltage characteristics, the relationship, I1=I2, holds all the time. As a result, in Comparative Example 2, a problem occurs that the current value supplied to the load 6 is limited by a smaller one of the current values I1 and I2. Therefore, it is impossible to supply a sufficient current to the load 6 to drive the load 6 (especially, the memory unit 61).

### Comparative Example 3

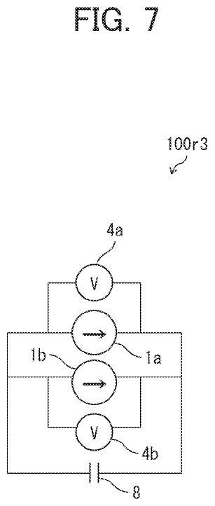

FIG. 7 is a diagram representing a circuit configuration of a sensor 100r3 in accordance with Comparative Example 3. Comparative Example 3 is another variation example of Comparative Example 1. In Comparative Example 3, the first sub-circuit 90a and the second sub-circuit 90b of Comparative Example 1 are connected in parallel. According to Comparative Example 3, similarly to Comparative Example 2, both the first solar cell module 1a and the second solar cell module 1b can supply electric power to the common load 6. In Comparative Example 3, similarly to Embodiment 1, the first solar cell module 1a and the second solar cell module 1b are connected in parallel. Therefore, the problem in Comparative Example 2 can also be solved in Comparative Example 3.

However, in Comparative Example 3, unlike Embodiment 1, no resistor 3 is provided. Therefore, in Comparative Example 3, regardless of whether the first solar cell module 1a and the second solar cell module 1b have the same or different current-voltage characteristics, the relationship, V1=V2, holds all the time. In other words, in Comparative Example 3, unlike Embodiment 1, it is impossible to set V1 and V2 to different values at any time.

Therefore, in Comparative Example 3, a problem occurs that the geolocation by the technique of Non-patent Literature 1 (hereinafter, “voltage-base geolocation”) is not applicable. This is because in voltage-base geolocation, geolocation calculations are performed by focusing on differences in how the time-series data of V1 and V2 changes.

### Effects of Sensor 100

In the sensor 100, the first solar cell module 1a and the second solar cell module 1b are connected. Therefore, the problem in Comparative Example 1 can be solved. In other words, according to the sensor 100, a compact sensor can be realized. Furthermore, in the sensor 100, the first solar cell module 1a and the second solar cell module 1b are connected in parallel. Therefore, as described above, the problem in Comparative Example 2 can also be solved.

In addition, in the sensor 100, the resistor 3 is interposed between the first solar cell module 1a and the second solar cell module 1b. Therefore, in the sensor 100, unlike Comparative Example 3, it is possible to set V1 and V2 to different values at a certain time. Therefore, in the sensor 100, it becomes possible to apply voltage-base geolocation. As described above, according to the sensor 100, the problem in Comparative Example 3 can also be solved.

### Additional Description

Non-patent Literature 1 discloses incorporating a solar cell as a power generation element into a sensor (EHAAS). A single solar cell has such a small output electric power that it is difficult to drive the load in the EHAAS by this output electric power. Therefore, a person skilled in the art would conceive of using, in place of a single solar cell, a solar cell module in which solar cells of the same type are connected in series or in parallel as a power generation element, to drive the load (see Comparative Examples 2 and 3).

In contrast, in the technique of Non-patent Literature 1, to perform voltage-base geolocation, individual circuits are provided by a plurality of solar cell modules having mutually different current-voltage characteristics (see Comparative Example 1). Then, the electric power generated by the plurality of solar cell modules is stored by a power storage element.

However, in the technique of Non-patent Literature 1, the electric power generated by each solar cell module is used solely to perform voltage-base geolocation. In addition, Non-patent Literature 1 does not disclose driving the load by the electric power stored in the power storage element. Furthermore, in the technique of Non-patent Literature 1, even if the electric power stored in the power storage element is used, it is impossible to drive a load that consumes much power (e.g., a load that has a memory unit).

Therefore, a person skilled in the art would, as described in Comparative Example 1, attempt to provide an additional solar cell module (or an additional power supply) to drive the load. A person skilled in the art would further attempt to reduce the resistance value of the circuit in the sensor as much as possible to supply more electric power to the load. Therefore, no person skilled in the art could easily conceive the sensor 100 (EHAAS including the resistor 3) from publicly known techniques. This is because a person skilled in the art would naturally rather contemplate excluding the resistor 3 from the components of the sensor (see Comparative Examples 1 to 3).

According to the sensor 100, similarly to the technique of Non-patent Literature 1, voltage-base geolocation is applicable. Therefore, in comparison to the technique of Patent Literature 1 (GPS geolocation), convenience in geolocation can be improved. Additionally, according to the sensor 100, unlike Non-patent Literature 1, it is also possible to supply the electric power generated by each solar cell module to the load 6. As described here, according to the sensor 100, it is possible to more efficiently use the electric power generated by the solar cell module.

### Embodiment 2

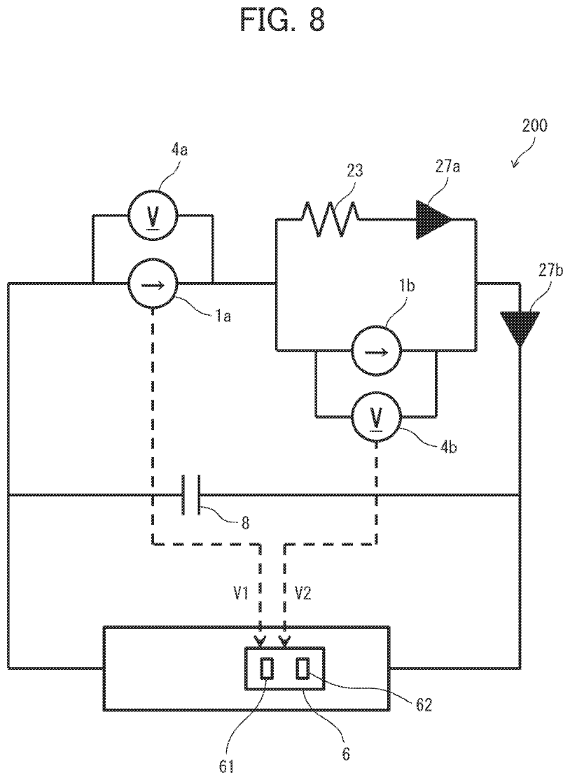

FIG. 8 is a diagram representing a circuit configuration of a sensor 200 in accordance with Embodiment 2. The sensor 200 is a variation example of the sensor 100. A resistor (first resistor) in the sensor 200 will be referred to as a resistor 23. Additionally, a first diode and a second diode in the sensor 200 will be referred to as a first diode 27a and a second diode 27b respectively.

In the sensor 200, unlike the sensor 100, the first solar cell module 1a and the second solar cell module 1b are connected in series with each other. Then, the resistor 23 is connected in series with the first solar cell module 1a and connected in parallel with the second solar cell module 1b. Taking this circuit configuration into account, the first diode 27a and the second diode 27b are disposed in different locations than the first diode 7a and the second diode 7b.

In the sensor 200, the resistor 23 is interposed between the first solar cell module 1a and the second solar cell module 1b. By the resistor 23, similarly to the resistor 3, it is possible to set V1 and V2 to different values at a certain time. In addition, in the sensor 200, similarly to the sensor 100, it is possible to supply the electric power generated by the first solar cell module 1a and the second solar cell module 1b to the load 6. Therefore, the sensor 200 achieves similar effects to the sensor 100.

Additional Description Whether the sensor 100 or the sensor 200 is to be used may be determined in accordance with the current-voltage characteristics of the first solar cell module 1a and the second solar cell module 1b under a certain illuminance. This point will be described in the following.

In the sensor 100 (the structure in which the first solar cell module 1a and the second solar cell module 1b are connected in parallel), the sum value, Pt1, of the output electric power generated by the first solar cell module 1a and the second solar cell module 1b is given by equation (7) below:

Pt1=P1 max+(P2 max−ΔVp max×Ip2 max) (7)

where ΔVp max=Vp1 max−Vp2 max.

Meanwhile, in the sensor 200 (the structure in which the first solar cell module 1a and the second solar cell module 1b are connected in series), the sum value, Pt2, of the output electric power generated by the first solar cell module 1a and the second solar cell module 1b is given by equation (8) below:

Pt2=P1 max+(P2 max−Vp2 max×ΔIp max) (8)

where ΔIp max=Ip1 max−Ip2 max.

To more reliably drive the load 6, the sum value of the output electric power generated by the first solar cell module 1a and the second solar cell module 1b is preferably large. Therefore, when Pt1>Pt2, the sensor 100 is preferably used. On the other hand, when Pt1<Pt2, the sensor 200 is preferably used.

Presume, as an example, that the illuminance is 200 1×. Calculating Pt1 and Pt2 under the illuminance of 200 1× by using the numerical values in FIG. 4, we obtain Pt1=556 μW and Pt2=358 μW. It can be concluded from this that in the example of FIG. 4, the sensor 100 is preferably used when the illuminance is 200 1×. However, if the load 6 does not consume so much power, the sensor 200 may be used.

### Embodiment 3

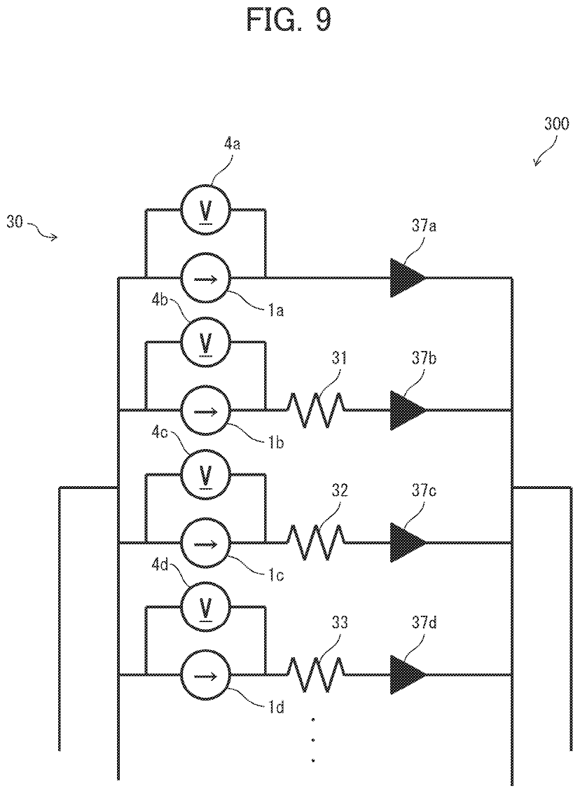

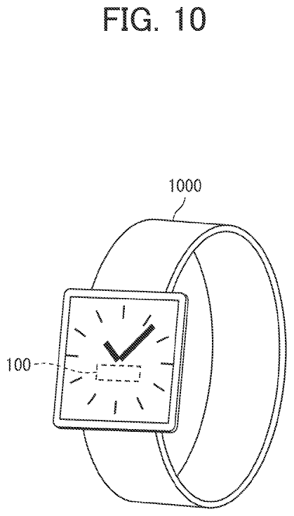

FIG. 9 is a diagram representing a circuit configuration of a sensor 300 in accordance with Embodiment 3. In FIG. 9, some members (e.g., the load 6) are omitted. The sensor 300 includes a group of solar cell modules 30. The group of solar cell modules 30 includes n solar cell modules. These n solar cell modules exhibit different current-voltage characteristics in the same illuminance environment, and n is any integer greater than or equal to 2. Note that the structure of the sensor 100 in FIG. 2 matches the structure of the sensor 300 in FIG. 9 whenn=2.

In the example of FIG. 9, an example is shown where n is somewhat large (e.g., n is larger than 4). In FIG. 9, of the n solar cell modules, four solar cell modules, a first solar cell module 1a to a fourth solar cell module id, are shown. In the sensor 300, the n solar cell modules are connected in parallel with each other.

In Embodiment 3, of the n solar cell modules, the solar cell module with the k-th largest output electric power will be referred to as the k-th solar cell module, where k is an integer from 1 to n, both inclusive. Therefore, in Embodiment 3, the first solar cell module 1a is the solar cell module with a maximum P max of the n solar cell modules. Similarly to Embodiment 1, it is preferable that P1 max<500 μW under the illuminance of 200 1×.

In the sensor 300, the k-th diode is provided so as to correspond one-to-one to the k-th solar cell module. In other words, n diodes, which are the first solar cell module 1a to an n-th solar cell module 1n, are provided. In FIG. 9, four diodes, which are a first diode 37a to a fourth diode 37d, are shown. The k-th diode is connected in series with the k-th solar cell module.

In the sensor 300, the k-th voltmeter is provided so as to correspond one-to-one to the k-th solar cell module. In other words, n voltmeters, which are the first voltmeter 4a to an n-th voltmeter 4n, are provided. In FIG. 9, four voltmeters, which are the first voltmeter 4a to a fourth voltmeter 4d, are shown. The k-th voltmeter is connected in parallel with the k-th solar cell module so as to measure a voltage Vk across the k-th solar cell module. As an example, the k-th voltmeter supplies a measured value of Vk obtained at every k-th time interval to the load 6. Therefore, the memory unit 61 can record the time-series data of V1 to Vn. The first to n-th time intervals may be either equal to each other or different from each other.

However, as described above, the k-th voltmeter does not need to measure Vk at every fixed time interval. The k-th voltmeter may measure Vk upon an acceleration sensor having detected in the acceleration a change that is greater than or equal to a prescribed amount.

In the sensor 300, n−1 resistors are provided so as to correspond to the n solar cell modules. Specifically, the (k−1)-th resistor is provided as a resistor corresponding to the k-th solar cell module. In FIG. 9, three resistors, a first resistor 31 to a third resistor 33, are shown. The resistance value of the k-th resistor will be referred to as R(k) throughout the following.

The (k−1)-th resistor is connected (i) in series with the k-th solar cell module and (ii) in parallel with the n−1 solar cell modules other than the k-th solar cell module. For instance, the first resistor 31 is connected (i) in series with the second solar cell module 1b and (ii) in parallel with each of the n−1 solar cell modules other than the second solar cell module 1b (i.e., the first solar cell module 1a and the third solar cell module 1c to the n-th solar cell module 1n).

In the sensor 300, the resistance values are set such that R(k−1)>R(k) for all k. In other words, the resistance values of the n−1 resistors are set such that R(1)>R(2)>R(3)> . . . >R(n−1). As described here, in the sensor 300, the k-th resistor which has the k-th largest resistance value, that is, R(k), is connected in series with the (k+1)-th solar cell module. For instance, the first resistor 31 (the resistor connected in series with the second solar cell module 1b) has the largest resistance value of the n−1 resistors. By setting R(1) to R(n−1) as described here, it is possible to set V1 to Vn to different values at a certain time.

In Embodiment 3, Ip(k)max denotes a maximum output operating current of the k-th solar cell module (the k-th maximum output operating current). Ip(k)max and Ip(k+1)max preferably also satisfy a similar relationship to equation (1) described above. In other words, following equation (9) preferably holds under the illuminance of 200 1×:

0.1 μA<|Ip(k)max−Ip(k+1)max|<500 μA (9).

In addition, in Embodiment 3, Vp(k)max denotes a maximum output operating voltage of the k-th solar cell module (the k-th maximum output operating voltage). Vp(k)max and Vp(k+1)max preferably also satisfy a similar relationship to equation (2) described above. In other words, equation (10) below preferably holds under the illuminance of 200 1×:

0.01 V<|Vp(k)max−Vp(k+1)max|<3 V (10).

### Effects of Sensor 300

According to the sensor 300, the voltages of the n solar cell modules (V1 to Vn) can be rendered different. In addition, the electric power (P1 to Pn) generated by the n solar cell modules can be supplied to the load 6. Therefore, the sensor 300 achieves similar effects to the sensor 100.

Furthermore, the precision of voltage-base geolocation is expected to improve with an increase in n (i.e., with an increasing number of solar cell modules). Therefore, according to the sensor 300, higher geolocation precision can be achieved. In addition, according to the sensor 300, each P1 to Pn can be reduced with an increase in n. In other words, even when the light-receiving areas of the n solar cell modules are set to small values, it is possible to generate a sufficient electric power to drive the load 6. Therefore, even when n has a large value, the sensor 300 can be made compact.

### Embodiment 4

FIG. 10 is an illustration of a smart watch 1000 (electronic device) in accordance with Embodiment 4. The smart watch 1000 is an example of a mobile electronic device. More specifically, the smart watch 1000 is an example of an information processing device (wearable device) that can be worn by a user. However, the mobile electronic device in accordance with an aspect of the present disclosure is not necessarily limited to a wearable device.

The smart watch 1000 includes a sensor in accordance with an aspect of the present disclosure (e.g., the sensor 100). In the example of FIG. 10, the sensor 100 is disposed below the face of the smart watch 1000. In other words, the sensor 100 is disposed on the front side when the smart watch 1000 is worn and viewed by the user. By disposing the sensor 100 as described here, the light projected toward each solar cell module is less likely to be blocked by the body of the user. Therefore, this location of the sensor 100 is suited to electric power generation by each solar cell module.

A control unit (not shown) of the smart watch 1000 acquires measured values of V1 and V2 (preferably, time-series data of V1 and V2) from the memory unit 61. Then, the control unit performs voltage-base geolocation by analyzing the measured values (preferably the time-series data). In other words, the smart watch 1000 geolocates the smart watch 1000 at a certain point in time (certain time; e.g., the current time) by analyzing the measured values.

Note that the load 6 does not necessarily include a memory unit 61 and a timer 62. In this case, the timer 62 needs only to be provided in the smart watch 1000. Then, the control unit of the smart watch 1000 needs only to acquire the measured values of V1 and V2 from the first voltmeter 4a and the second voltmeter 4b respectively. The sensor 100 may include (i) a control unit of the smart watch 1000 and (ii) any communication interface for communications between the first voltmeter 4a and the second voltmeter 4b.

### Variation Examples

(1) An electronic device of an aspect of the present disclosure is not necessarily limited to a mobile electronic device. The electronic device may be a desktop type of electronic device. However, a sensor of an aspect of the present disclosure is typically realized as a compact sensor. Therefore, the sensor is particularly suitable for application to mobile electronic devices. This is because in the case of a mobile electronic device, in comparison to a desktop type of electronic device, there is a large demand to reduce the size of the device. Furthermore, there is a larger demand to provide a voltage-base geolocation function to the mobile electronic device than to the desktop type of electronic device.

(2) In an aspect of the present disclosure, the voltage-base geolocation function is not necessarily provided in the electronic device including the sensor 100. The sensor 100 may, for example, be connected to a cloud server (not shown) in a communicable manner. In this case, the voltage-base geolocation function may be provided in the cloud server. As an example, the cloud server acquires the measured values of V1 and V2 from the first voltmeter 4a and the second voltmeter 4b respectively. Then, the cloud server performs voltage-base geolocation. Subsequently, the cloud server supplies the geolocation information obtained by the voltage-base geolocation (information representing the sensor 100 at a certain time) to the smart watch 1000.

(3) In an aspect of the present disclosure, the sensor 100 may have a voltage-base geolocation function. As an example, when the load 6 includes a relatively high performance processor, the sensor 100 may have a voltage-base geolocation function.

### Software Implementation

The control blocks of the sensors 100 to 300 and the smart watch 1000 (particularly, the control units of the load 6 and the smart watch 1000) may be implemented by logic circuits (hardware) fabricated, for example, in the form of integrated circuits (IC chips) and may be implemented by software.

In the latter form of implementation, the sensors 100 to 300 and the smart watch 1000 include a computer that executes instructions from programs or software by which various functions are provided. This computer includes among others at least one processor (control device) and at least one storage medium containing the programs in a computer-readable format. The processor in the computer then retrieves and runs the programs contained in the storage medium, thereby achieving the object of an aspect of the present disclosure. The processor may be, for example, a CPU (central processing unit). The storage medium may be a “non-transitory, tangible medium” such as a ROM (read-only memory), a tape, a disc/disk, a card, a semiconductor memory, or programmable logic circuitry. The sensors 100 to 300 and the smart watch 1000 may further include, for example, a RAM (random access memory) for loading the programs. The programs may be supplied to the computer via any transmission medium (e.g., over a communications network or by broadcasting waves) that can transmit the programs. The present disclosure, in an aspect thereof, encompasses data signals on a carrier wave that are generated during electronic transmission of the programs.

### Additional Remarks

The present disclosure, in an aspect thereof, is not limited to the description of the embodiments above and may be altered within the scope of the claims. Embodiments based on a proper combination of technical means disclosed in different embodiments are encompassed in the technical scope of the aspect of the present disclosure. Furthermore, new technological features can be created by combining different technical means disclosed in the embodiments.

### CROSS-REFERENCE TO RELATED APPLICATIONS

The present application claims the benefit of priority to Japanese Patent Application, Tokugan, No. 2020-026631 filed on Feb. 19, 2020, the entire contents of which are incorporated herein by reference.

### REFERENCE SIGNS LIST

1a First Solar Cell Module
1b Second Solar Cell Module
3, 23 Resistor
4a First Voltmeter
4b Second Voltmeter
6 Load
10, 30 Group of Solar Cell Modules
31 First Resistor (Resistor)
61 Memory Unit
62 Timer
100, 200, 300 Sensor
1000 Smart Watch (Electronic Device)
P1 max First Maximum Output Electric Power (Maximum Output Electric Power of First Solar Cell Module)
P2 max Second Maximum Output Electric Power (Maximum Output Electric Power of Second Solar Cell Module)
Ip1 max First Maximum Output Operating Current (Current in First Solar Cell Module When Output Electric Power of First Solar Cell Module is Maximum)
Ip2 max Second Maximum Output Operating Current (Current in Second Solar Cell Module When Output Electric Power of Second Solar Cell Module is Maximum)
Vp1 max First Maximum Output Operating Voltage (Voltage across First Solar Cell Module When Output Electric Power of First Solar Cell Module is Maximum)
Vp2 max Second Maximum Output Operating Voltage (Voltage across Second Solar Cell Module When Output Electric Power of Second Solar Cell Module is Maximum)
V1 Voltage across First Solar Cell Module (First Voltage)
V2 Voltage across Second Solar Cell Module (Second Voltage)

1. A sensor for use in an energy harvesting system, the sensor comprising:
a first solar cell module;
a second solar cell module connected to the first solar cell module; and
a resistor connected in parallel with one of the first solar cell module and the second solar cell module and in series with another one of the first solar cell module and the second solar cell module, wherein the first solar cell module and the second solar cell module have mutually different current-voltage characteristics in a same illuminance environment, and
the sensor further comprising:
a first voltmeter configured to measure a first voltage that is a voltage across the first solar cell module;
a second voltmeter configured to measure a second voltage that is a voltage across the second solar cell module; and
a load to which an electric power generated by the first solar cell module and the second solar cell module is supplied.

2. The sensor according to claim 1, wherein
the load includes a memory unit, and
the memory unit records time-series data of the first voltage measured by the first voltmeter and time-series data of the second voltage measured by the second voltmeter.

3. The sensor according to claim 1 or 2, wherein
P1 max>P2 max under an illuminance of 200 1×, where P1 max denotes a maximum output electric power of the first solar cell module and P2 max denotes a maximum output electric power of the second solar cell module, and
the resistor is connected in parallel with the first solar cell module and in series with the second solar cell module.

4. The sensor according to any one of claims 1 to 3, wherein
the first voltmeter measures the first voltage at every first time interval, and
the second voltmeter measures the second voltage at every second time interval.

5. The sensor according to claim 4, wherein the first time interval is equal to the second time interval.

6. The sensor according to any one of claims 1 to 3, further comprising an acceleration sensor, wherein
the first voltmeter measures the first voltage, and the second voltmeter measures the second voltage, both upon the acceleration sensor having detected in acceleration a change that is greater than or equal to a prescribed amount.

7. The sensor according to any one of claims 1 to 6, wherein 0.1 μA<|Ip1 max−Ip2 max|<500 μA under an illuminance of 200 1×, where Ip1 max denotes a current in the first solar cell module when the first solar cell module produces a maximum output electric power, and Ip2 max denotes a current in the second solar cell module when the second solar cell module produces a maximum output electric power.

8. The sensor according to any one of claims 1 to 7, wherein 0.01 V<|Vp1 max−Vp2 max|<3 V under an illuminance of 200 1×, where Vp1 max denotes the first voltage when the first solar cell module produces a maximum output electric power, and Vp2 max denotes the second voltage when the second solar cell module produces a maximum output electric power.

9. The sensor according to any one of claims 1 to 8, wherein 50 μW<P1 max<500 μW, and 50 μW<P2 max<500 μW, both under an illuminance of 200 1×, where P1 max denotes a maximum output electric power of the first solar cell module, and P2 max denotes a maximum output electric power of the second solar cell module.

10. The sensor according to any one of claims 1 to 9, wherein P1 max>P2 max under an illuminance of 200 1× and under an illuminance of 500 1×, where P1 max denotes a maximum output electric power of the first solar cell module, and P2 max denotes a maximum output electric power of the second solar cell module.

11. The sensor according to claim 10, wherein P1 max>P2 max under any illuminance of from 200 1× to 500 1×, both inclusive.

12. An electronic device comprising the sensor according to any one of claims 1 to 11.

13. The electronic device according to claim 12, the electronic device analyzing the first voltage measured by the first voltmeter and the second voltage measured by the second voltmeter for geolocation of the electronic device.
